(19) United States
(12) Patent Application Publication
(10) Pub. No.: US 2010/0258342 A1
(43) Pub. Date: Oct. 14, 2010

(54) BONDED HERMETIC FEED THROUGH FOR AN ACTIVE IMPLANTABLE MEDICAL DEVICE

(75) Inventor: John L. Parker, Roseville (AU)

Correspondence Address: CONNOLLY BOVE LODGE & HUTZ LLP, 1875 EYE STREET, N.W., SUITE 1100, WASHINGTON, DC, 20006, US

(73) Assignee: National ICT Australia Limited (NICTA), Alexandria (AU)

(21) Appl. No.: 12/549,875

(22) Filed: Aug. 28, 2009

(30) Foreign Application Priority Data
Apr. 8, 2009 (AU) 2009901530

(51) Int. Cl. H05K 1/11; H05K 13/00

(52) U.S. Cl. 174/266; 29/852; 174/262

(57) ABSTRACT

A feed through for an active implantable medical device (AIMD). The feed through comprises first and second substantially planar, electrically non-conductive and fluid impermeable substrates usable for semiconductor device fabrication, each comprising: an aperture there through, and a contiguous metalized layer on the substrate surface that is co-existent with a section of the perimeter of the aperture and extends from the aperture; and a bond layer affixing the metalized layers of the first and second substrates to one another such that the apertures are not aligned with one another, and such that the metalized regions form a conductive pathway between the apertures.

### CROSS-REFERENCE TO RELATED APPLICATION

The present application claims priority from Australian Provisional Patent Application No. 2009901530, filed Apr. 8, 2009, which is hereby incorporated by reference herein.

The present application is related to commonly owned and co-pending U.S. Utility patent applications entitled “Knitted Electrode Assembly For An Active Implantable Medical Device,” filed Aug. 28, 2009, “Knitted Electrode Assembly And Integrated Connector For An Active Implantable Medical Device,” filed Aug. 28, 2009, “Knitted Catheter,” filed Aug. 28, 2009, “Stitched Components of An Active Implantable Medical Device,” filed Aug. 28, 2009, and “Electronics Package For An Active Implantable Medical Device,” filed Aug. 28, 2009, which hereby incorporated by reference herein.

### BACKGROUND

1. Field of the Invention

The present invention relates generally to active implantable medical devices (AIMDs), and more particularly, to a bonded feed through for an AIMD.

2. Related Art

Medical devices having one or more active implantable components, generally referred to herein as active implantable medical devices (AIMDs), have provided a wide range of therapeutic benefits to patients over recent decades. AIMDs often include an implantable, hermetically sealed electronics module, and a device that interfaces with a patient's tissue, sometimes referred to as a tissue interface. The tissue interface may include, for example, one or more instruments, apparatus, sensors or other functional components that are permanently or temporarily implanted in a patient. The tissue interface is used to, for example, diagnose, monitor, and/or treat a disease or injury, or to modify a patient's anatomy or physiological process.

In particular applications, an AIMD tissue interface includes one or more conductive electrical contacts, referred to as electrodes, which deliver electrical stimulation signals to, or receive signals from, a patient's tissue. The electrodes are typically disposed in a biocompatible electrically non-conductive member, and are electrically connected to the electronics module. The electrodes and the non-conductive member are collectively referred to herein as an electrode assembly.

### SUMMARY

In accordance with one aspect of the present invention, a method for manufacturing a feed through for an implantable medical device is provided. The method comprises: forming an aperture through each of first and second substantially planar, electrically non-conductive and fluid impermeable substrates usable for semiconductor device fabrication; metalizing a region of a surface of the first substrate to form a contiguous metalized layer that is co-existent with a section of the perimeter of the aperture and extends from the aperture; metalizing a region of a surface of the second substrate to form a contiguous metalized layer that is co-existent with a section of the perimeter of the aperture and extends from the aperture; bonding the metalized layers to one another such that the apertures are not aligned with one another, and such that the metalized layers form a conductive pathway between the apertures.

In accordance with another aspect of the present invention, a feed through for an implantable medical device is provided. The feed through comprises: first and second substantially planar, electrically non-conductive and fluid impermeable substrates usable for semiconductor device fabrication, each comprising: an aperture there through, and a contiguous metalized layer on the substrate surface that is co-existent with a section of the perimeter of the aperture and extends from the aperture; and a bond layer affixing the metalized layers of the first and second substrates to one another such that the apertures are not aligned with one another, and such that the metalized regions form a conductive pathway between the apertures.

In accordance with a still other aspect of the present invention, a method for manufacturing a feed through for an implantable medical device is provided. The method comprises: forming an aperture through each of first and second substantially planar, electrically non-conductive and fluid impermeable substrates usable for semiconductor device fabrication; metalizing a region of a surface of the first substrate to form a contiguous metalized layer that is co-existent with a section of the perimeter of the aperture and extends from the aperture; metalizing a region of a surface of the second substrate to form a contiguous metalized layer that is co-existent with a section of the perimeter of the aperture and extends from the aperture; and bonding the metalized layers to opposing surfaces of a third substantially planar, electrically non-conductive and fluid impermeable substrate usable for semiconductor device fabrication, having at least one conductive region disposed there through that forms a conductive pathway between the metalized layers.

In accordance with another aspect of the present invention, a feed through for an implantable medical device is provided. The feed through comprises: first and second substantially planar, electrically non-conductive and fluid impermeable substrates usable for semiconductor device fabrication, each comprising: an aperture there through, and a contiguous metalized layer on the substrate surface that is co-existent with a section of the perimeter of the aperture and extends from the aperture; and a third substantially planar, electrically non-conductive and fluid impermeable substrate usable for semiconductor device fabrication, having at least one conductive region extending there through; and first and second bond layers affixing the metalized layers of the first and second substrates to opposing surfaces of a third substrate such that the conductive region provides a conductive pathway between the metalized layers.

### BRIEF DESCRIPTION OF THE DRAWINGS

Aspects and embodiments of the present invention are described herein with reference to the accompanying drawings, in which:

FIG. 1 is a perspective view of an exemplary active implantable medical device (AIMD), namely a neurostimulator, comprising a knitted electrode assembly in accordance with embodiments of the present invention;

FIG. 2 is a functional block diagram of the neurostimulator illustrated in FIG. 1, in accordance with embodiments of the present invention;

FIG. 3A is a flowchart illustrating a method for manufacturing a hermetic feed through, in accordance with embodiments of the present invention;

FIG. 3B is a flowchart illustrating a method for manufacturing a hermetic feed through, in accordance with embodiments of the present invention;

FIG. 4A is a perspective view of two substrates usable to form a feed through in accordance with embodiments of the present invention each having an aperture therein;

FIG. 4B is a perspective view of the two substrates of FIG. 4A each having a metalized layer formed on a surface thereof;

FIG. 4C is a perspective view of the two substrates of FIG. 4B positioned for bonding, in accordance with embodiments of the present invention;

FIG. 4D is a perspective view of a feed through in accordance with embodiments of the present invention formed by bonding the substrates of FIG. 4C to one another;

FIG. 4E is a cross-sectional side view of the feed through of FIG. 4D;

FIG. 5A is a perspective view of two substrates usable to form a feed through in accordance with embodiments of the present invention each having an aperture therein;

FIG. 5B is a perspective view of the two substrates of FIG. 5A each having a metalized layer formed on a surface thereof;

FIG. 5C is a cross-sectional side view of a third substrate having a conductive region disposed therein, in accordance with embodiments of the present invention;

FIG. 5D is a cross-sectional side view of a feed through formed using the substrates of FIGS. 5A-5C;

FIG. 6A is a cross-sectional side view of two bonded substrates in accordance with embodiments of the present invention;

FIG. 6B illustrates the bonded substrates of FIG. 6A having an aperture in one of the substrates plated with a conductive material;

FIG. 6C illustrates the bonded substrates of FIG. 6B having the plated aperture filled with a conductive material;

FIG. 6D illustrates the bonded substrates of FIG. 6C having a conductive layer disposed over the filled aperture;

FIG. 7A is a cross-sectional side view of a substrate having a trench formed therein;

FIG. 7B illustrates the substrate of FIG. 7A having a conducting layer disposed on the surface thereof;

FIG. 7C illustrates the substrate of FIG. 7B having the conducting layer disposed only in the trench, in accordance with embodiments of the present invention;

FIG. 8A is a top view of an integrated circuit (IC) electrically connected to a feed through in accordance with embodiments of the present invention;

FIG. 8B is a cross-sectional side view of the IC and electrically connected feed through of FIG. 8A;

FIG. 9A is a top view of a feed through in accordance with embodiments of the present invention;

FIG. 9B is a cross-sectional side view of the feed through of FIG. 9A; and

FIG. 10 is a cross-sectional side view of a feed through and hermetically sealed cavity in accordance with embodiments of the present invention.

### DETAILED DESCRIPTION

Aspects of the present invention are generally directed to an active implantable medical device (AIMD) comprising an implantable, hermetically sealed electronics module and a tissue interface. The tissue interface is electrically connected to the electronics module through a hermetic feed through. The hermetic feed through comprises two or more substantially planar, electrically non-conductive and fluid impermeable substrates usable for semiconductor device fabrication. The substrates are prepared and directly bonded to one another to form a hermetically sealed electrical connection there through.

More specifically, in certain embodiments the hermetic feed through is formed using first and second substrates. In such embodiments, each substrate has an aperture there through, and has a contiguous metalized layer on the substrate surface that is co-existent with a section of the perimeter of the aperture and which extends from the aperture. The first and second substrates are affixed to one another by a bond layer such that the apertures are not aligned with one another, and such that the metalized layers form a conductive pathway between the apertures.

In other embodiments, the hermetic feed through is formed using three substrates. In such embodiments, first and second substrates each have an aperture there through, and a contiguous metalized layer on the substrate surface that is co-existent with a section of the perimeter of the aperture and which extends from the aperture. The third substrate comprises a substantially planar, electrically non-conductive and fluid impermeable substrate usable for semiconductor device fabrication, having at least one conductive region extending there through. The first and second substrates are affixed to opposing surfaces of the third substrate such that that the conductive region provides a conductive pathway between the metalized layers.

Embodiments of the present invention are described herein primarily in connection with one type of AIMD, a neurostimulator, and more specifically a deep brain stimulator or spinal cord stimulator. Deep brain stimulators are a particular type of AIMD that deliver electrical stimulation to a patient's brain, while spinal cord stimulators deliver electrical stimulation to a patient's spinal column. As used herein, deep brain stimulators and spinal cord stimulators refer to devices that deliver electrical stimulation alone or in combination with other types of stimulation. It should be appreciated that embodiments of the present invention may be implemented in any brain stimulator (deep brain stimulators, cortical stimulators, etc.), spinal cord stimulator or other neurostimulator now known or later developed, such as cardiac pacemakers/defibrillators, functional electrical stimulators (FES), pain stimulators, etc. Embodiments of the present invention may also be implemented in AIMDs that are implanted for a relatively short period of time to address acute conditions, as well in AIMDs that are implanted for a relatively long period of time to address chronic conditions.

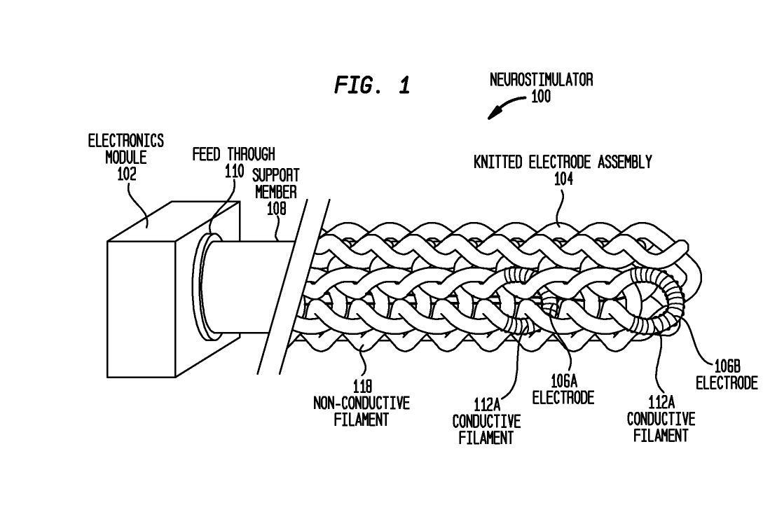

FIG. 1 is a perspective view of an active implantable medical device (AIMD), namely a neurostimulator 100, in accordance with embodiments of the present invention. Neurostimulator 100 comprises an implantable, hermetically sealed electronics module 102, and a tissue interface, shown as knitted electrode assembly 104. Although FIG. 1 illustrates the use of knitted electrode assembly 104, it should be appreciated that embodiments of the present invention may implemented with other types of tissue interfaces.

Knitted electrode assembly 104 comprises a biocompatible, electrically non-conductive filament arranged in substantially parallel rows each stitched to an adjacent row. Electrode assembly 104 further comprises two biocompatible, electrically conductive filaments 112 intertwined with non-conductive filament 118. In the embodiments of FIG. 1, the wound sections of conductive filaments 112 form electrodes 106 which deliver electrical stimulation signals to, or receive signals from, a patient's tissue. A knitted electrode assembly is described in greater detail in commonly owned and co-pending U.S. Utility patent application entitled “Knitted Electrode Assembly for an Active Implantable Medical Device,” filed Aug. 28, 2009, the content of which are hereby incorporated by reference herein.

In the embodiments of FIG. 1, a portion of each conductive filament 112 extends through the interior of electrode assembly 104 to a resiliently flexible support member 108 that mechanically couples knitted electrode assembly 104 to electronics module 102. A hermetic feed through 110 in accordance with embodiments of the present invention is disposed at the proximal end of support member 108 for electrically connecting filaments 112 to electronics module 102. Details of an exemplary feed through are provided below.

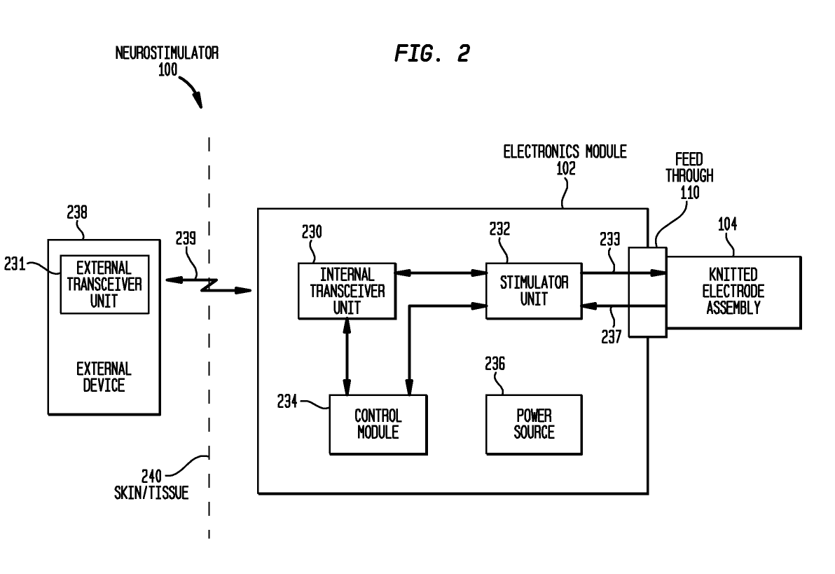

FIG. 2 is a functional block diagram illustrating one exemplary arrangement of electronics module 102 of neurostimulator 100 of the present invention. In the embodiments of FIG. 2, electronics module 102 is implanted under a patient's skin/tissue 240, and cooperates with an external device 238. External device 238 comprises an external transceiver unit 231 that forms a bi-directional transcutaneous communication link 239 with an internal transceiver unit 230 of electronics module 102. Transcutaneous communication link 239 may be used by external device 238 to transmit power and/or data to electronics module 102. Similarly, transcutaneous communication link 239 may be used by electronics module 102 to transmit data to external device 238.

As used herein, transceiver units 230 and 231 each include a collection of one or more components configured to receive and/or transfer power and/or data. Transceiver units 230 and 231 may each comprise, for example, a coil for a magnetic inductive arrangement, a capacitive plate, or any other suitable arrangement. As such, in embodiments of the present invention, various types of transcutaneous communication, such as infrared (IR), electromagnetic, capacitive and inductive transfer, may be used to transfer the power and/or data between external device 238 and electronics module 102.

In the specific embodiment of FIG. 2, electronics module 102 further includes a stimulator unit 232 that generates electrical stimulation signals 233. Electrical stimulation signals 233 are provided to electrodes 106 (FIG. 1) of knitted electrode assembly 104 via feed through 110. Electrodes 106 deliver electrical stimulation signals 233 to a patient's tissue. Stimulator unit 232 may generate electrical stimulation signals 233 based on, for example, data received from external device 238, signals received from a control module 234, in a pre-determined or pre-programmed pattern, etc.

As noted above, in certain embodiments, electrodes 106 of knitted electrode assembly 104 are configured to record or monitor the physiological response of a patient's tissue. In such embodiments, signals 237 representing the recorded response may be provided to stimulator unit 232 via feed through 110 for forwarding to control module 234, or to external device 238 via transcutaneous communication link 239.

In the embodiments of FIG. 2, neurostimulator 100 is a totally implantable medical device that is capable of operating, at least for a period of time, without the need for external device 238. Therefore, electronics module 102 further comprises a rechargeable power source 236 that stores power received from external device 238. The power source may comprise, for example, a rechargeable battery. During operation of neurostimulator 100, the power stored by the power source is distributed to the various other components of electronics module 102 as needed. For ease of illustration, electrical connections between power source 236 and the other components of electronics module 102 have been omitted. FIG. 2 illustrates power source 236 located in electronics module 102, but in other embodiments the power source may be disposed in a separate implanted location.

FIG. 2 illustrates specific embodiments of the present invention in which neurostimulator 100 cooperates with an external device 238. It should be appreciated that in alternative embodiments, deep brain stimulation 100 may be configured to operate entirely without the assistance of an external device.

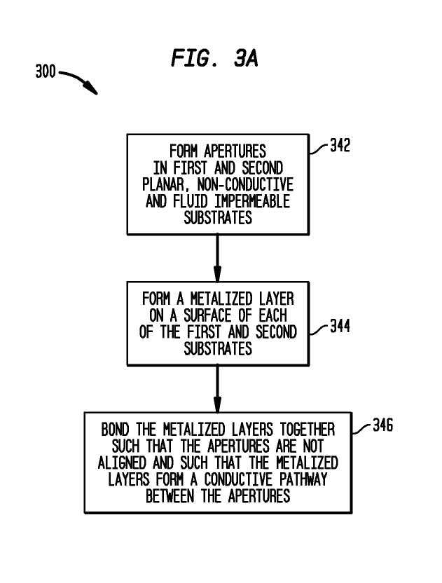

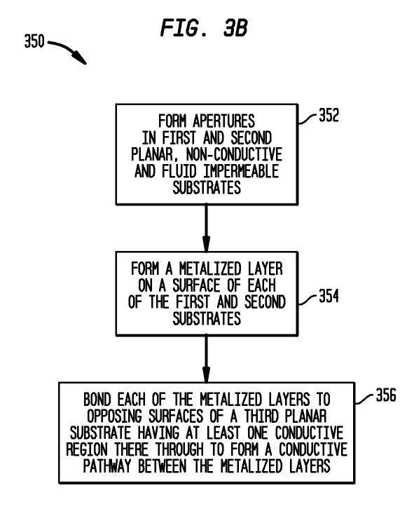

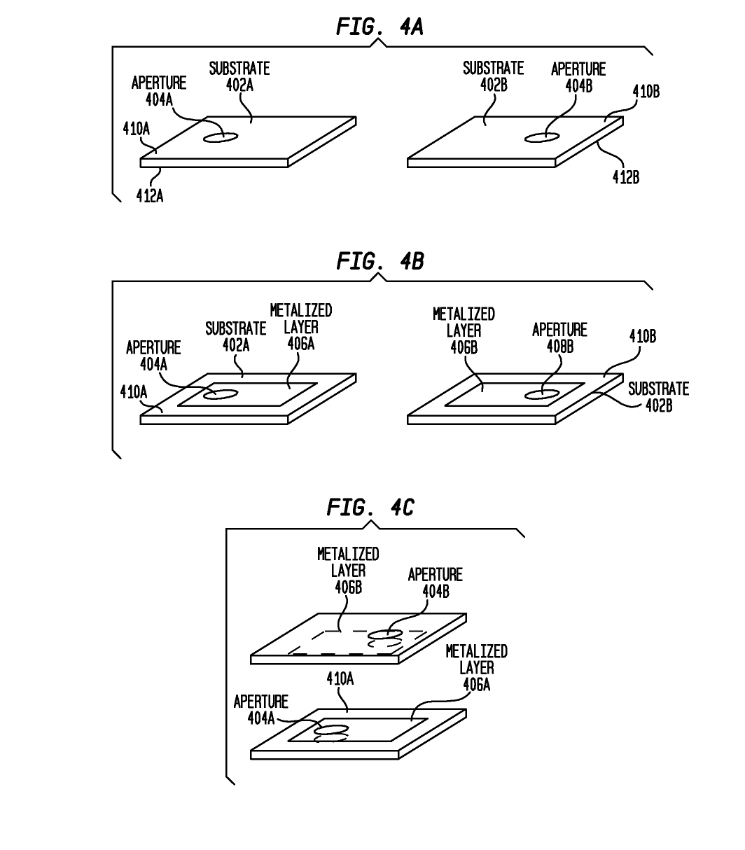

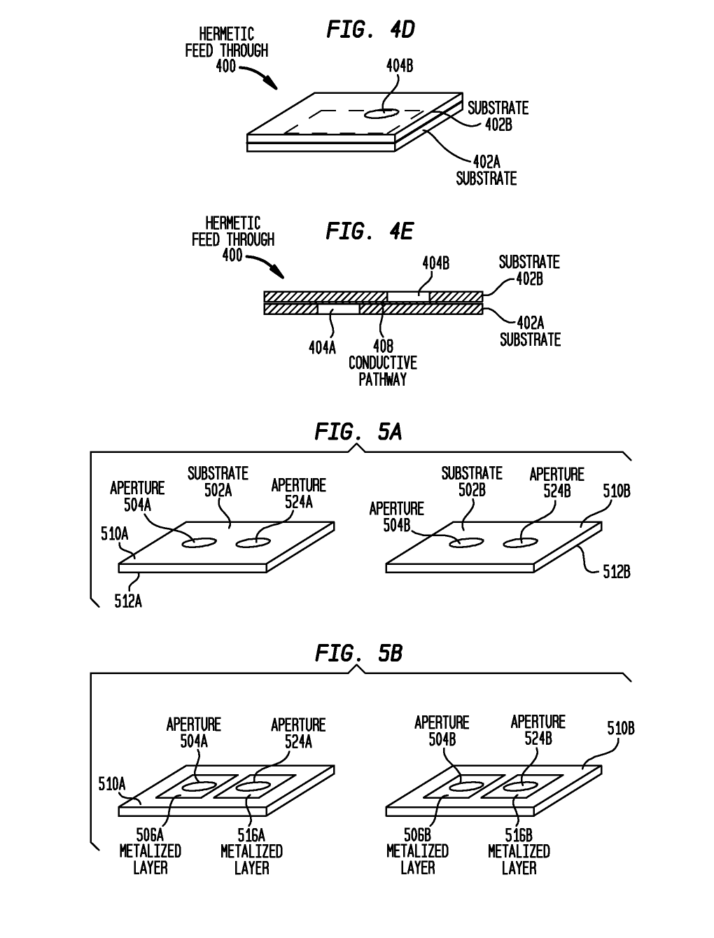

As noted above, embodiments of the present invention are directed to a hermetic feed through for an AIMD formed using two or more bonded substrates. FIG. 3A is a flowchart illustrating a method 300 for manufacturing a hermetic feed through in accordance with embodiments of the present invention. FIGS. 4A-4E illustrate the elements resulting from, or used in, the steps of FIG. 3A. For ease of explanation, the embodiments of FIG. 3A will be described with reference to the elements illustrated in FIGS. 4A-4E.

As noted, substrates utilized in accordance with embodiments of the present invention are substantially planar, electrically non-conductive and fluid impermeable substrates that are suitable for use in semiconductor device fabrication (i.e. in the production of electronic components and integrated circuits). For example, substrates in accordance with certain embodiments of the present invention are compatible with conventional silicon processing technology. Suitable substrates include, but are not limited to, sapphire substrates, silicon substrates and ceramic substrates.

Method 300 illustrated in FIG. 3A begins at block 342 where an aperture is formed in each of first and second substrates. FIG. 4A illustrates exemplary substrates 402 each having opposing surfaces 410, 412. Apertures 404 extend between the opposing surfaces of each substrate 402. Various methods such as, for example, laser drilling, mechanical drilling, grit drilling, ion etching, punching, stamping, photolithography etc. may be implemented to form apertures in the substrates. It should be appreciated that the selected method for forming an aperture may depend on the desired shape and/or size of the aperture, as well as the type of substrate. For instance, in circumstances where sapphire substrates are used, the apertures are formed using laser drilling (i.e. with a Nd-YAG laser). It should also be appreciated that certain methods are not desirable for all substrate types.

For ease of illustration, FIGS. 4A-4E illustrates embodiments in which a single aperture 404 is formed in each substrate 402. It should be appreciated that other embodiments in which a greater number of apertures are utilized are in the scope of the present invention.

Furthermore, the embodiments of FIGS. 4A-4E illustrate the formation and use of round apertures. It should be appreciated that the aperture geometry may be chosen to suit the feed through application, and may be adapted for connection to certain devices required in a specific application, shape of the feed through, number of desired feed through channels, etc. As such, the aperture geometry is not limited.

As described below, in the embodiments of FIG. 3A, substrates 402A, 402B are bonded to one another to form a hermetic feed through. To facilitate bonding of the substrates, the surfaces to be bonded (referred to herein as “bonding surfaces”), are planarized, polished and/or otherwise treated as is well known in the art to remove debris and any other surface deformation. Debris removal may be required subsequent to the formation of the apertures to remove any contaminates introduced in this process. These processes provide sufficiently smooth surfaces for bonding. The smoothness of the surfaces may depend on, for example, the selected bonding process to be utilized at a later stage. In certain embodiments, the planarization/polishing may be omitted by initially providing a substrate having a surface that is sufficiently smooth. Such a surface may be provided by cutting a substrate along a crystal plane.

At block 344 of FIG. 3A, a region of each bonding surface 410 is metalized to form a metalized layer 406 thereon. As used herein, the metallization of a substrate surface refers to the coating of a region of the surface with a thin film of conductive metallic material such as platinum or titanium.

FIG. 4B illustrates the formation of metalized layers 406 on each surface 410. As shown, each metalized layer 406 is co-existent with a section of the perimeter of an aperture 404. That is, each metalized layer 406 extends to and adjoins the perimeter of the aperture 404. Each metalized layer 406 further extends from the aperture 404 in at least one direction. As described below, metalized layers 406 extend a distance from the aperture 404 that is sufficient to create a hermetically sealed conductive pathway between the two aperture openings during the bonding process.

In specific embodiments, the metalized layers 406 are formed using thin-film deposition techniques. In such embodiments, the first and second substrates are placed in a deposition chamber and then a metal film is deposited thereon. It should be appreciated that other methods are within the scope of the present invention. It should also be appreciated that the shape of the metalized layers may vary, so along as the metalized layer is co-existent with a section of the perimeter of apertures 404, and so that the region extends a distance from the opening. These different shapes may be formed, for example, through post deposition patterning using laser ablation, or during deposition via masking.

At block 346 of method 300, metalized layers 406 are bonded to one another. In particular, during deposition or shortly thereafter, metalized layers 406 are brought into contact with each other. In certain embodiments, metalized layers 406 are brought together using a low pressure force that may be, for example, less than 40 μbar. As shown in FIG. 4C, metalized layers 406 are bonded to one another such that apertures 404 are not aligned with one another, and such that the metalized layers form a conductive pathway between the apertures. Non-alignment of apertures 404 refers to the fact that the distance between the longitudinal axis of the two apertures is greater that the sum of the two radii of the aperture openings, plus an added desired distance that is sufficient to ensure a hermetic seal between the apertures. In other words, apertures 404 do not overlap one another, and are separated so as to prevent the flow of fluid there between. The distance between apertures 404 may be varied so long as the hermetic seal is maintained.

In particular embodiments of the present invention, a method of bonding the substrates during thin film sputter deposition is utilized. In these embodiments, the metalized layers (each having a thickness of 10-20 nm) are brought together and bonded at room temperature. The bonding occurs through diffusion of the metal between the two opposing metalized layers. As noted above, this process utilizes very smooth and contamination free films having a film surface roughness that is sufficiently smaller than the self-diffusion length of metals.

It should be appreciated that a number of other bonding techniques may also be employed to bond metalized layers 406 to one another. Exemplary other bonding techniques include, but are not limited to, thermo-sonic bonding where heat and ultra sound energy are applied via the substrate to the interface, metal brazing where laser energy of an appropriate wavelength is directed at the interface to achieve a welded joint, soldering with an appropriate solder (eg gold) or other forms of brazing or reflow of metallic interlayer. There are also a number of processes for bonding wafers without a metallic interlayer such as anodic bonding and room temperature wafer level bonding (Ziptronix). Anodic bonding occurs between a sodium rich glass substrate and polysilicon film. The bond is formed at a temperature to mobilize the ions in the glass and voltage (typically 1000 Volts). The applied potential causes the sodium to deplete from the interface and an electrostatic bond is formed. These processes bond the substrates directly together and are of utility in joining the non-metalized portions of the substrates.

FIGS. 4D and 4E illustrate perspective and cross-sectional side views, respectively, of a feed through 400 formed using the above described method. FIG. 4E illustrates a conductive pathway 408 formed by the bonding of metalized layers 406 to one another.

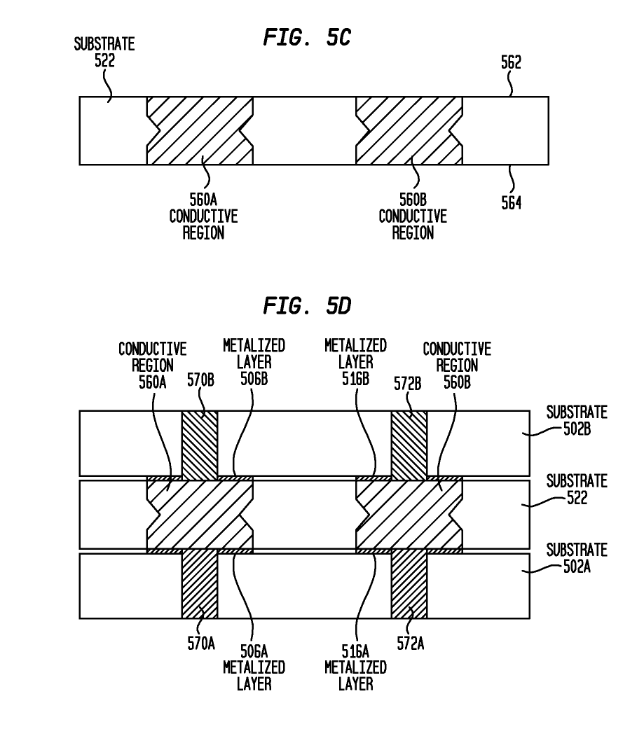

As noted above, certain embodiments of the present invention are directed to a hermetic feed through for an AIMD formed using three bonded substrates. FIG. 3B is a flowchart illustrating a method 350 for manufacturing a hermetic feed through in accordance with such embodiments of the present invention. FIGS. 5A-5D illustrate the elements resulting from, or used in, the steps of FIG. 3B. For ease of explanation, the embodiments of FIG. 3B will be described with reference to the elements illustrated in FIGS. 5A-5D.

As noted above, substrates utilized in accordance with embodiments of the present invention are substantially planar, electrically non-conductive and fluid impermeable substrates that are suitable for use in semiconductor device fabrication. For example, substrates in accordance with embodiments of the present invention are compatible with conventional silicon processing technology. Suitable substrates include, but are not limited to, sapphire substrates, silicon substrates and ceramic substrates.

Method 350 illustrated in FIG. 3B begins at block 352 where two apertures are formed in each of first and second substrates. FIG. 5A illustrates exemplary substrates 502 each having opposing surfaces 510, 512. Apertures 504 and 524 extend between the opposing surfaces of each substrate 502. As noted above, various methods may be implemented to form apertures in substrates 502. Also as noted, the selected method for forming an aperture may depend on the desired shape and/or size of the aperture, as well as the type of substrate.

FIGS. 5A-5D illustrate embodiments in which two apertures 504 and 524 are formed in each substrate 502. It should be appreciated that other embodiments in which a greater or lesser number of apertures are utilized are in the scope of the present invention. Furthermore, embodiments of the present invention illustrate round apertures, but it should be appreciated that the aperture geometry may be chosen to suit the desired application, and is not limited.

As described below, in the embodiments of FIG. 3B, substrates 502A, 502B are each bonded to opposing surfaces of a third substrate to form a hermetic feed through. To facilitate bonding of the substrates, the surfaces to be bonded (referred to herein as “bonding surfaces”) are planarized, polished and/or otherwise treated as is well known in the art to remove debris and any other surface deformation. As noted above, the desired smoothness of the surfaces may depend on, for example, the selected bonding process to be utilized at a later stage. Also as noted, in certain embodiments, the planarization/polishing may be omitted by initially providing a substrate having a surface that is sufficiently smooth. Such a surface may be provided by cutting a substrate along a crystal plane.

At block 354 of method 350, a region of each bonding surface 510 is metalized to form metalized layers 506, 516. As used herein, the metallization of a substrate surface refers to the coating of a region of the surface with a thin film of conductive metallic material such as platinum or titanium.

FIG. 5B illustrates the formation of two metalized layers 506 and 516 on each surface 510. As shown, each metalized layer 506, 516 is co-existent with a section of the perimeter of an aperture 504, 524, respectively. That is, each metalized layer 506, 516 extends to and adjoins an aperture 504, 524. Each metalized layer 506 further extends a distance from the aperture 504, 524 in at least one direction. As described below, metalized layers 506, 516 extend a distance from the aperture 504, 524 that is sufficient to provide a conductive pathway between the aperture and a conductive region of a third substrate.

In specific embodiments, metalized layers 506, 516 are formed using thin-film deposition techniques. It should be appreciated that other methods are within the scope of the present invention. It should also be appreciated that the shape of metalized layers 506, 516 may vary, so long as the metalized layer is co-existent with a section of the perimeter of an aperture 504, 524. These different shapes may be formed, for example, through post deposition patterning using laser ablation, or during deposition via masking.

At block 356 of method 350, metalized layers 506, 516 are bonded to a third substrate. FIG. 5C is a cross-sectional view of an exemplary third substrate 522 that may be utilized in accordance with embodiments of the present invention. Substrate 522 may be an anisotropic conductor or a wafer of silicon. In the illustrative embodiments of FIG. 5C, substrate 522 has two conductive regions 560 extending there through. In certain embodiments, conductive regions 560 are formed by diffusing a metallic element, such as boron, through substrate 522, to forms a low resistance path through the substrate.

In these embodiments of the present invention, surfaces 562, 564 of substrate 522 are each bonded to surfaces 510 of one of substrates 502. The bonding methods described above with reference to FIG. 3A may also be used in these embodiments of the present invention. In particular, during deposition or shortly thereafter, metalized layers 506, 516 are brought into contact with conductive regions 560.

In the illustrative embodiments of FIG. 5B, conductive regions 560 provide a conductive pathway between opposing metalized layers 506, 516 of substrates 502, while preventing the flow of fluid between opposing apertures 504, 524. As such, opposing apertures 504, 524 may be aligned with one another, or non-aligned, depending on the desired configuration.

The embodiments described above with reference to FIGS. 3A-5D disclose the bonding of two substrates to one another. It should be appreciated that any number of substrates may be bonded to one another using the embodiments described above to form a stacked configuration. In such embodiments, all stacked substrates are electrically connected to one another to form a continuous electrical pathway.

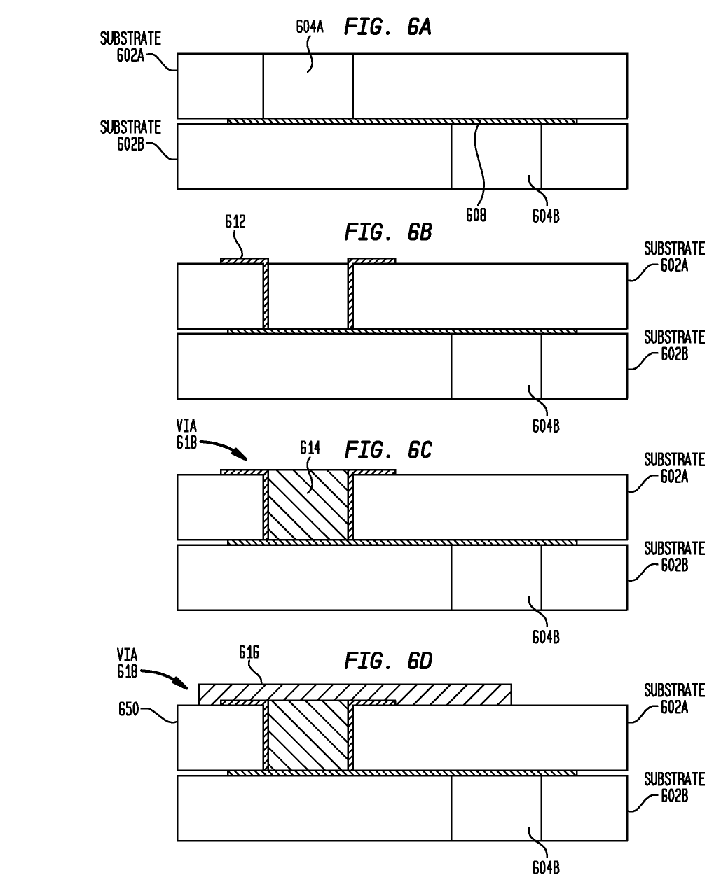

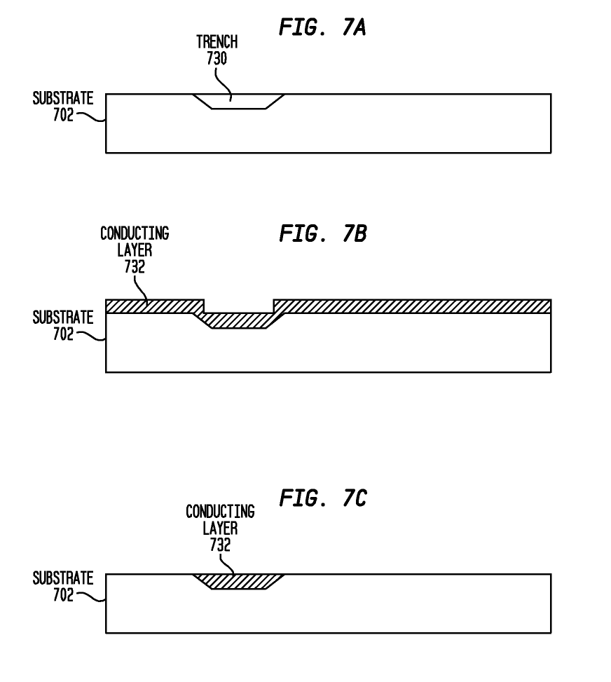

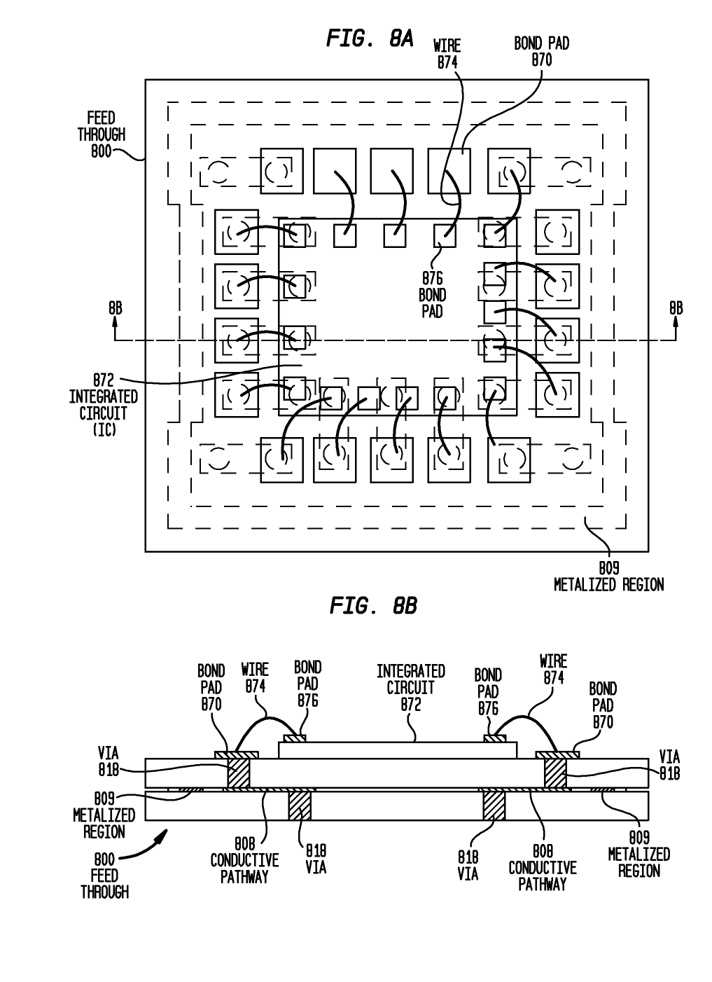

In certain embodiments of the present invention, the apertures within the bonded substrates are each formed into plated through holes, referred to herein as a via. FIGS. 6A-6D illustrate the conversion of an aperture into a via in accordance with embodiments of the present invention. In these embodiments, two substrates 602A, 602B are prepared and bonded to one another as described with reference to FIG. 3A. As shown in FIG. 6A, substrates 602 each have an aperture 604 there through. Apertures 604 are electrically connected to one another by conductive pathway 608. For ease of illustration, the conversion of an aperture of a via will be described with reference to a single aperture 604A. It should be appreciated that a similar process may be applied to convert aperture 604B into a via.

To convert aperture 604A into a via, the internal walls of aperture 604A, as well as the surface of substrate 602A surrounding aperture 604A are plated with a suitable conductive material using, for example, vacuum deposition. This plating process, shown in FIG. 6B, creates an electrical connection between aperture 604A and conductive pathway 608.

Next, as shown in FIG. 6C, plated aperture 604A is filled with a bulk material 614 using, for example, electroplating methods. The filled aperture 604A is referred to as via 618. As shown in FIG. 6D, a conductive material 616 may then be deposited over via 618 to form a bond pad for connecting via 618 to other components.

As noted above with reference to the embodiments of FIGS. 3A and 4A-4E, following the bonding process two apertures 404 are electrically connected by a conductive pathway 408. The resistivity of a section of the conductive pathway 408 is generally given by Equation (1):

$$ρ = \frac{RA}{l} \qquad Equation ( 1 )$$

Where ρ is the static resistivity (measured in ohm meters, Ω-m); R is the electrical resistance of a section of the conductive pathway (measured in ohms, Ω); l is the length of the section of the conductive pathway (measured in meters, m); and A is the cross-sectional area of the section of the conductive pathway (measured in square meters, m²).

It may be desirable to obtain as low a resistivity as possible along conductive pathway 408. Acceptable resistivity of a few Ohms may be achieved through design of the conductive pathway by manipulating the inputs to Equation (1). In other words, the resistivity may be affected by altering the length or area of the conductive pathway, or by using different conductive materials. However, certain designs may require a resistivity that is difficult to achieve by manipulating the inputs to Equation (1). FIGS. 7A-7C illustrate a method for further reducing the resistivity of a conductive pathway. In these embodiments, a trench 730 is formed in a first substrate 702 as shown in FIG. 7A. Next, trench 730 and the surface of substrate 702 are coated with a conducting metal layer 732 which is thickened using, for example, electroplating, as shown in FIG. 7B. After thickening of conducting layer 732, substrate 702 is planarized and/or polished using conventional techniques so that conducting layer 732 remains only in trench 730. Substrate 702 having the plated trench therein may then be used as substrate in the embodiments described above with reference to FIGS. 3A and 3B. It should be appreciated that alternative methods for forming a thickened substrate to improve conductivity may also be utilized in embodiments of the present invention.

FIG. 8A is a top of a feed through in accordance with embodiments of the present invention electrically connected to an Integrated Circuit (IC). FIG. 8B is a cross-sectional side view of the arrangement of FIG. 8A taken along line 8B-8B.

Similar to the embodiments described above, feed through 800 comprises vias 818 that are hermetically sealed from one another, and which are electrically connected to one another via a conductive pathway 808. As shown, IC 872 is positioned directly over feed through 800 and is wire bonded, to the feed through. Specifically, wires 874 are used to electrically connect bond pads 870 of the feed through to bond pads 876 of IC 872.

As noted, FIGS. 8A and 8B illustrate embodiments in which an IC is wire bonded to one side of feed through 800. It should be appreciated that in embodiments of the present invention feed through 800 may be bonded to IC 872 using alternative techniques. For instance, in alternative embodiments flip chip bonding may be used to electrically connect IC 872 to feed through 800.

As noted above, in accordance with embodiments of the present invention metalized regions are provided between apertures to provide a conductive pathway. In certain embodiments of the present invention, a feed through may include one or more additional metalized regions which, rather than providing a conductive pathway, form a hermetic barrier. One such exemplary metalized region 809 is illustrated in FIGS. 8A and 8B. As shown, metalized region surrounds the periphery of feed through 800 to prevent the ingress of bodily fluids.

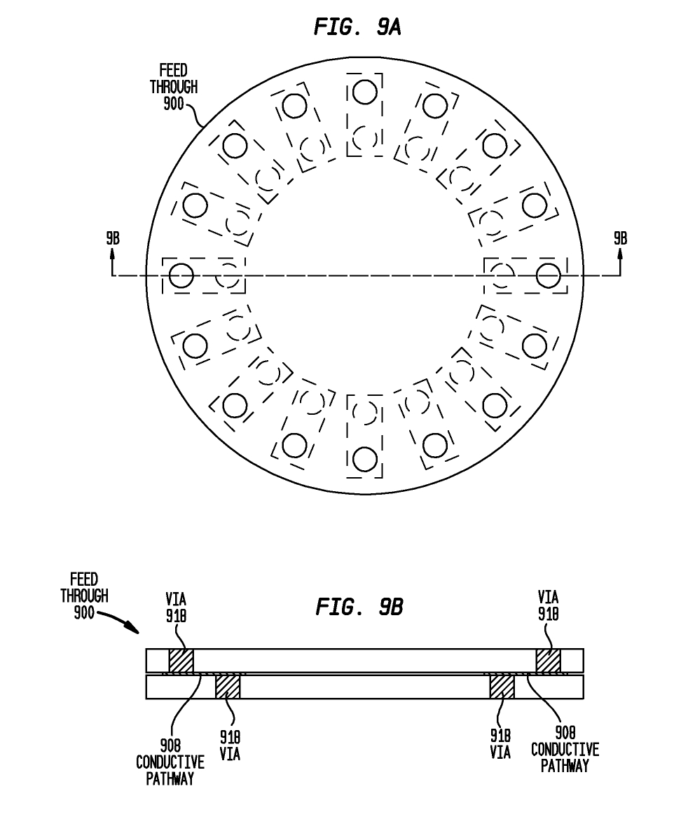

FIG. 9A illustrates a top view of a circular feed through 900 in accordance with embodiments of the present invention. FIG. 9B is a cross-sectional view of feed through 900 taken along line denoted 9B-9B. Similar to the embodiments described above, feed through 900 comprises vias 918 that are hermetically sealed from one another, and which are electrically connected to one another via a conductive pathway 908.

FIGS. 9A-9B illustrate a circular feed through comprising multiple feed through channels. It should be appreciated that the circular arrangement of FIGS. 9A and 9B is merely illustrative and that other arrangements are within the scope of the present invention.

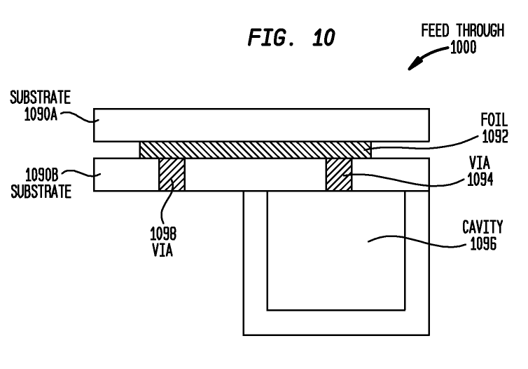

FIG. 10 illustrates a feed through 1000 in accordance with further embodiments of the present invention. In these embodiments, feed through 1000 comprises first and second substrates 1090. Substrate 1090 has two vias 1094, 1098, formed therein. Via 1094 extends between a hermetically sealed cavity 1096 and a planarized metal foil 1092 bonded between substrates 1090 using, for example, one of the bonding methods described above. Metal foil 1092 forms a conductive pathway between via 1094 and via 1098. As such, via 1098 is electrically connected to one or more components with cavity 1096.

The present application is related to commonly owned and co-pending U.S. Utility patent applications entitled “Knitted Electrode Assembly For An Active Implantable Medical Device,” filed Aug. 28, 2009, “Knitted Electrode Assembly And Integrated Connector For An Active Implantable Medical Device,” filed Aug. 28, 2009, “Knitted Catheter,” filed Aug. 28, 2009, “Stitched Components of An Active Implantable Medical Device,” filed Aug. 28, 2009, and “Electronics Package For An Active Implantable Medical Device,” filed Aug. 28, 2009. The contents of these applications are hereby incorporated by reference herein.

While various embodiments of the present invention have been described above, it should be understood that they have been presented by way of example only, and not limitation. It will be apparent to persons skilled in the relevant art that various changes in form and detail may be made therein without departing from the spirit and scope of the invention. Thus, the breadth and scope of the present invention should not be limited by any of the above-described exemplary embodiments, but should be defined only in accordance with the following claims and their equivalents. All patents and publications discussed herein are incorporated in their entirety by reference thereto.

What is claimed is:

1. A method for manufacturing a feed through for an implantable medical device, comprising:
forming an aperture through each of first and second substantially planar, electrically non-conductive and fluid impermeable substrates usable for semiconductor fabrication;
metalizing a region of a surface of the first substrate to form a contiguous metalized layer that is co-existent with a section of the perimeter of the aperture and extends from the aperture;
metalizing a region of a surface of the second substrate to form a contiguous metalized layer that is co-existent with a section of the perimeter of the aperture and extends from the aperture;
bonding the metalized layers to one another such that the apertures are not aligned with one another, and such that the metalized layers form a conductive pathway between the apertures.

2. The method of claim 1, further comprising:
forming a plurality of apertures in the first and second substrates.

3. The method of claim 2, further comprising:
metalizing a region of a surface of the first substrate to form a plurality of physically separate metalized layers each co-existent with a section of the perimeter of one of the plurality of apertures and each extending from the one aperture; and
metalizing a region of a surface of the second substrate to form a plurality of physically separate metalized layers each co-existent with a section of the perimeter of one of the plurality of apertures and each extending from the one aperture.

4. The method of claim 3, further comprising:
bonding each of the metalized layers of the first substrate to a separate metalized layer of the second substrate such that no aperture openings are aligned with one another, and such that each of the bonded metalized layers form a conductive pathway between apertures.

5. The method of claim 1, further comprising:
forming through vias in each of the first and second apertures.

6. The method of claim 5, wherein forming the vias in each of the first and second apertures comprises:
coating the aperture cavity with a conductive material;
filling the coated cavity with a bulk conductive material; and
disposing a conductive material over the filled aperture.

7. The method of claim 1, further comprising:
providing a conductive trench in the first substrate prior to forming the aperture therein.

8. The method of claim 1, wherein bonding the metalized layers to one another comprises:
forming a metal layer bond.

9. The method of claim 1, further comprising:
preparing the first and second substrates for bonding prior to metalizing the substrate surfaces.

10. A feed through for an implantable medical device, comprising:
first and second substantially planar, electrically non-conductive and fluid impermeable substrates usable for semiconductor device fabrication, each comprising:
an aperture there through, and
a contiguous metalized layer on the substrate surface that is co-existent with a section of the perimeter of the aperture and extends from the aperture; and
a bond layer affixing the metalized layers of the first and second substrates to one another such that the apertures are not aligned with one another, and such that the metalized regions form a conductive pathway between the apertures.

11. The feed through of claim 10, wherein each of the first and second substrates comprise a plurality of apertures there through.

12. The feed through of claim 11, wherein each of the substrates further comprise:
a plurality of physically separate metalized layers on the surfaces of the substrate each co-existent with a section of the perimeter of one of the plurality of apertures and each extending from the one aperture.

13. The feed through of claim 12, further comprising:
a plurality of bond layers affixing each of the metalized layers of the first substrate to a separate metalized layer of the second substrate such that no apertures are aligned with one another, and such that each of the bonded metalized layers form a conductive pathway between apertures.

14. The feed through of claim 10, further comprising:
vias formed in each of the first and second apertures.

15. The feed through of claim 10, wherein the first substrate comprises:
a conductive trench formed therein.

16. The feed through of claim 10, wherein the bonded layer comprises a metal layer bond.

17. A method for manufacturing a feed through for an implantable medical device, comprising:
forming an aperture through each of first and second substantially planar, electrically non-conductive and fluid impermeable substrates usable for semiconductor device fabrication;
metalizing a region of a surface of the first substrate to form a contiguous metalized layer that is co-existent with a section of the perimeter of the aperture and extends from the aperture;
metalizing a region of a surface of the second substrate to form a contiguous metalized layer that is co-existent with a section of the perimeter of the aperture and extends from the aperture; and
bonding the metalized layers to opposing surfaces of a third substantially planar, electrically non-conductive and fluid impermeable substrate usable for semiconductor device fabrication, having at least one conductive region disposed there through that forms a conductive pathway between the metalized layers.

18. The method of claim 17, further comprising:
bonding each of the metalized layers to the third substrate such that the apertures in the first and second substrates are substantially aligned with one another.

19. The method of claim 17, further comprising:
bonding each of the metalized layers to the third substrate such that the apertures in the first and second substrates are not aligned with one another.

20. The method of claim 17, further comprising:
providing a third substrate that comprises an anisotropic conductor.

21. The method of claim 17, further comprising:
providing a third substrate that comprises a wafer of silicon.

22. The method of claim 21, further comprising:
diffusing a metallic element in the silicon wafer to form a low resistance path through the wafer.

23. The method of claim 17, further comprising:
forming through vias in each of the first and second apertures.

24. The method of claim 17, further comprising:
providing a conductive trench in the first substrate prior to forming the aperture therein.

25. A feed through for an implantable medical device, comprising:
first and second substantially planar, electrically non-conductive and fluid impermeable substrates usable for semiconductor device fabrication, each comprising:
an aperture there through, and
a contiguous metalized layer on the substrate surface that is co-existent with a section of the perimeter of the aperture and extends from the aperture; and
a third substantially planar, electrically non-conductive and fluid impermeable substrate usable for semiconductor device fabrication, having at least one conductive region extending there through; and
first and second bond layers affixing the metalized layers of the first and second substrates to opposing surfaces of a third substrate such that the conductive region provides a conductive pathway between the metalized layers.

26. The feed through of claim 25, wherein the apertures in the first and second substrates are substantially aligned with one another.

27. The feed through of claim 25, wherein the apertures in the first and second substrates are not aligned with one another.

28. The feed through of claim 25, wherein the third substrate comprises an anisotropic conductor.

29. The feed through of claim 25, wherein the third substrate comprises a wafer of silicon.

30. The feed through of claim 29, wherein the wafer of silicon comprises a diffused metallic region extending there through to form a low resistance path through the wafer.

31. The feed through of claim 25, further comprising:
vias formed in each of the first and second apertures.

32. The feed through of claim 25, wherein the first substrate comprises:
a conductive a trench formed therein.
